(19) United States
(12) Patent Application Publication
(10) Pub. No.: US 2025/0267964 A1
(43) Pub. Date: Aug. 21, 2025

(54) APPARATUS AND EQUIPMENT

(71) Applicant: CANON KABUSHIKI KAISHA, Tokyo (JP)

(72) Inventors: DAIKI SHIRAHIGE, Kanagawa (JP); TAKAFUMI MIKI, Kanagawa (JP)

(21) Appl. No.: 19/047,032

(22) Filed: Feb. 6, 2025

(30) Foreign Application Priority Data
Feb. 16, 2024 (JP) 2024-021763

(51) Int. Cl. H10F 39/00; H10F 39/18

(52) U.S. Cl. CPC H10F 39/8027; H10F 39/182; H10F 39/8063; H10F 39/807

(57) ABSTRACT

An apparatus includes a first pixel and a second pixel, wherein each of them includes a first photoelectric conversion element, a second photoelectric conversion element, a third photoelectric conversion element, and a fourth photoelectric conversion element, and a floating diffusion portion, wherein a first element isolation region including a trench structure is disposed between the first pixel and the second pixel, wherein a second element isolation region including a trench structure is disposed between the first photoelectric conversion element and the second photoelectric conversion element, wherein a third element isolation region including a trench structure is arranged between the first photoelectric conversion element and the third photoelectric conversion element, and wherein a length in the first direction of the trench structure in the second element isolation region is larger than a length in the second direction of the trench structure in the third element isolation region.

### BACKGROUND

### Technical Field

The aspect of the embodiments relates to a photoelectric conversion apparatus and an equipment.

### Description of the Related Art

A photoelectric conversion apparatus on which a plurality of pixels are arranged adjacent to each other has been known. Each of the pixels includes a plurality of photoelectric conversion elements and a floating diffusion portion shared by the plurality of photoelectric conversion elements. For example, Japanese Patent Application Laid-Open No. 2023-3799 discusses a configuration in which one pixel includes four photoelectric conversion elements arrayed in a 2-by-2 matrix and a floating diffusion portion arranged between the four photoelectric conversion elements, and an isolation portion having a trench structure is arranged between the photoelectric conversion elements within the pixel.

With the configuration discussed in Japanese Patent Application Laid-Open No. 2023-3799, in a case where amounts of signal charges generated in the four photoelectric conversion elements arranged in the pixel are different, there is a possibility that signal charges flowing out of the first photoelectric conversion element flow into the photoelectric conversion elements arrayed in a row and a column directions. In this case, execution of phase difference detection becomes difficult with respect to a specific direction because appropriate signals may not be acquired.

### SUMMARY

According to an aspect of the embodiments, an apparatus comprising a first pixel configured to receive light via a first microlens and a second pixel configured to receive light via a second microlens. Each of the first pixel and the second pixel is disposed on a semiconductor substrate having a first face and a second face opposite to the first face, and includes a first photoelectric conversion element and a second photoelectric conversion element sequentially arranged in a first direction, a third photoelectric conversion element and a fourth photoelectric conversion element sequentially arranged in the first direction, and a floating diffusion portion shared by the first photoelectric conversion element, the second photoelectric conversion element, the third photoelectric conversion element, and the fourth photoelectric conversion element. The first photoelectric conversion element and the third photoelectric conversion element are sequentially arranged in a second direction intersecting with the first direction, and the second photoelectric conversion element and the fourth photoelectric conversion element are sequentially arranged in the second direction. The floating diffusion portion is disposed between the first photoelectric conversion element and the fourth photoelectric conversion element and between the second photoelectric conversion element and the third photoelectric conversion element. A first element isolation region including a trench structure is disposed between the first pixel and the second pixel. In the first pixel, a second element isolation region including a trench structure is disposed between the first photoelectric conversion element and the second photoelectric conversion element, and a third element isolation region including a trench structure is disposed between the first photoelectric conversion element and the third photoelectric conversion element. In a planar view of the first face, an area of the trench structure in the second element isolation region is different from an area of the trench structure in the third element isolation region. A difference between the area of the trench structure in the second element isolation region and the area of the trench structure in the third element isolation region is 5% or more.

Further features of the disclosure will become apparent from the following description of exemplary embodiments with reference to the attached drawings.

### BRIEF DESCRIPTION OF THE DRAWINGS

FIG. 1 is a block diagram illustrating a photoelectric conversion apparatus according to a first exemplary embodiment.

FIG. 2 is a diagram illustrating a configuration of a unit.

FIG. 3 is a diagram illustrating a configuration of a unit.

FIG. 4 is a drive timing diagram illustrating operation of the photoelectric conversion apparatus.

FIG. 5 is a diagram illustrating a configuration of a lamination type photoelectric conversion apparatus.

FIGS. 6A and 6B are plan views illustrating the photoelectric conversion apparatus according to the first exemplary embodiment.

FIG. 7 is a diagram illustrating potential levels with respect to signal charges in the photoelectric conversion apparatus according to the first exemplary embodiment.

FIG. 8 is a plan view illustrating a photoelectric conversion apparatus according to a first variation example of the first exemplary embodiment.

FIG. 9 is a plan view illustrating a photoelectric conversion apparatus according to a second variation example of the first exemplary embodiment.

FIGS. 10A and 10B are plan views illustrating a photoelectric conversion apparatus according to a second exemplary embodiment.

FIGS. 11A is a plan view illustrating a photoelectric conversion apparatus according to a variation example of a second exemplary embodiment. FIG. 11B is a diagram illustrating an example of a cross sectional face of the photoelectric conversion apparatus in FIG. 11A.

FIG. 12A is a plan view illustrating a photoelectric conversion apparatus according to a variation example of the third exemplary embodiment. FIG. 12B is a diagram illustrating an example of a cross sectional face of the photoelectric conversion apparatus in FIG. 12A.

FIG. 13 is a plan view illustrating a concept of a photoelectric conversion apparatus according to a fourth exemplary embodiment.

FIG. 14 is a plan view illustrating a photoelectric conversion apparatus according to the fourth exemplary embodiment.

FIG. 15 is a plan view illustrating a photoelectric conversion apparatus according to a variation example of the fourth exemplary embodiment.

FIGS. 16A to 16C are schematic diagrams illustrating an equipment according to a fifth exemplary embodiment.

### DESCRIPTION OF THE EMBODIMENTS

Hereinafter, exemplary embodiments will be described with reference to the appended drawings. The exemplary embodiments described below are not intended to limit the disclosure according to the scope of the appended claims. Although a plurality of features is described in the exemplary embodiments, not all of the features are essentially required for the disclosure, and the plurality of features may be combined optionally. In the appended drawings, the same reference numerals are applied to constituent elements identical or similar to each other, and duplicative descriptions thereof are omitted. In the below-described exemplary embodiments, a complementary metal oxide semiconductor (CMOS) sensor is mainly described as an example of the photoelectric conversion apparatus. However, the exemplary embodiments are not limited to the CMOS sensor, and can also be applied to examples other than the photoelectric conversion apparatus. For example, the exemplary embodiments can also be applied to a charge coupled device (CCD) sensor, an image capturing apparatus, a range-finding apparatus (i.e., a distance measurement apparatus employing a focus detection technique and/or a Time-of-Flight (TOF) technique), and a light measurement apparatus (i.e., an apparatus for measuring an amount of incident light).

In this specification documents, wordings which describe particular directions and positions, (e.g., “up”, “down”, “right”, “left”, and other wordings including these wordings) are used as necessary. These wordings are used for the sake of easy understanding of the exemplary embodiments described with reference to the appended drawings, and the meanings of these wordings should not be construed as limiting the technical range of the disclosure.

In the present specification documents, “plane face” refers to a face parallel to a main face of a semiconductor substrate.

Further, “plan view” refers to a view from a direction perpendicular to the main face of the semiconductor substrate. Further, “cross-sectional face” refers to a face perpendicular to a light-incident face of a semiconductor layer. Furthermore, “cross-sectional view” refers to a view from a direction parallel to the main face of the semiconductor substrate.

The main face of the semiconductor substrate can be a light incident face of the semiconductor substrate including photoelectric conversion elements, a face on which a plurality of analog-to-digital (AD) conversion units are arranged repeatedly, or a bonding face where one substrate and another substrate of a lamination type photoelectric conversion apparatus are bonded together.

In this specification documents, an impurity concentration of each semiconductor region is a concentration of impurities contributing to the behavior as a semiconductor region of a predetermined conductive type, and is not a concentration corresponding to the actual ion implantation amount. In other words, the impurity concentration refers to a difference between a donor concentration and an acceptor concentration. This impurity concentration is called a net doping concentration. For example, in a case where impurities (donors) for making a semiconductor region become an N-type are included in a semiconductor region behaving as a P-type semiconductor region, a concentration of the impurities (donors) for making the semiconductor region become an N-type is subtracted from a concentration of the impurities (acceptors) for making the semiconductor region become a P-type. The subtracted concentration is then treated as an impurity concentration for making the semiconductor region become a predetermined conductive type.

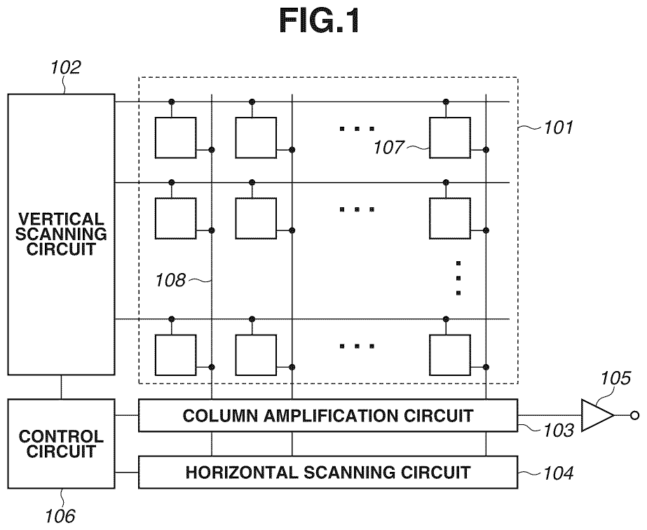

A configuration of a photoelectric conversion apparatus according to a first exemplary embodiment of the disclosure will now be described with reference to FIGS. 1 to 9.

FIG. 1 is an example of a block diagram illustrating a schematic configuration of the photoelectric conversion apparatus according to the present exemplary embodiment. The photoelectric conversion apparatus includes a pixel array 101, a vertical scanning circuit 102, a column amplification circuit 103, a horizontal scanning circuit 104, an output circuit 105, and a control circuit 106. The photoelectric conversion apparatus in FIG. 1 is a semiconductor apparatus formed on a semiconductor substrate such as a silicon substrate.

The pixel array 101 includes a plurality of pixels 107 two-dimensionally arranged in a first direction D1 and a second direction D2 intersecting with the first direction D1 of the semiconductor substrate. For example, the first direction D1 is a row direction, whereas the second direction D2 is a column direction. The vertical scanning circuit 102 supplies a plurality of control signals for controlling and making a plurality of transistors included in the pixels 107 become ON (conduction) states or OFF (non-conduction) states. On each column of pixels 107, a column signal line 108 is provided, and signals output from the pixels 107 are read out to the column signal line 108 column by column. The column amplification circuit 103 amplifies pixel signals output to the column signal line 108, and executes processing, such as correlated double sampling processing, based on signals output from the pixels 107 at the time of reset and at the time of photoelectric conversion. The horizontal scanning circuit 104 supplies a control signal to turn a switch connected to an amplifier of the column amplification circuit 103 on and off. The control circuit 106 controls the vertical scanning circuit 102, the column amplification circuit 103, and the horizontal scanning circuit 104. The output circuit 105 includes a buffer amplifier and a differential amplifier, and outputs pixel signals output from the column amplification circuit 103 to a signal processing unit provided on the outside of an image capturing apparatus. The photoelectric conversion apparatus may also include an AD conversion unit to output digital pixel signals.

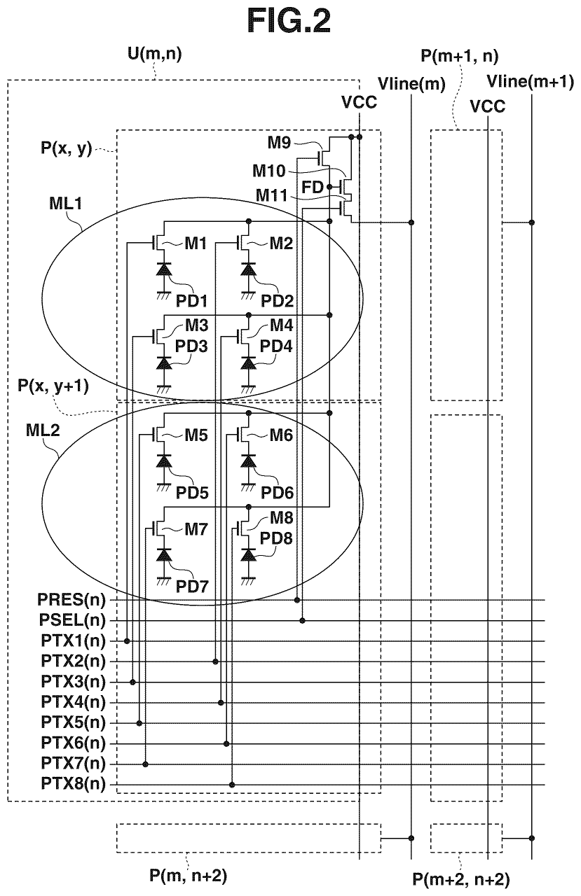

In FIG. 2, a unit U includes a pixel P(x, y) and a pixel P(x, y+1).

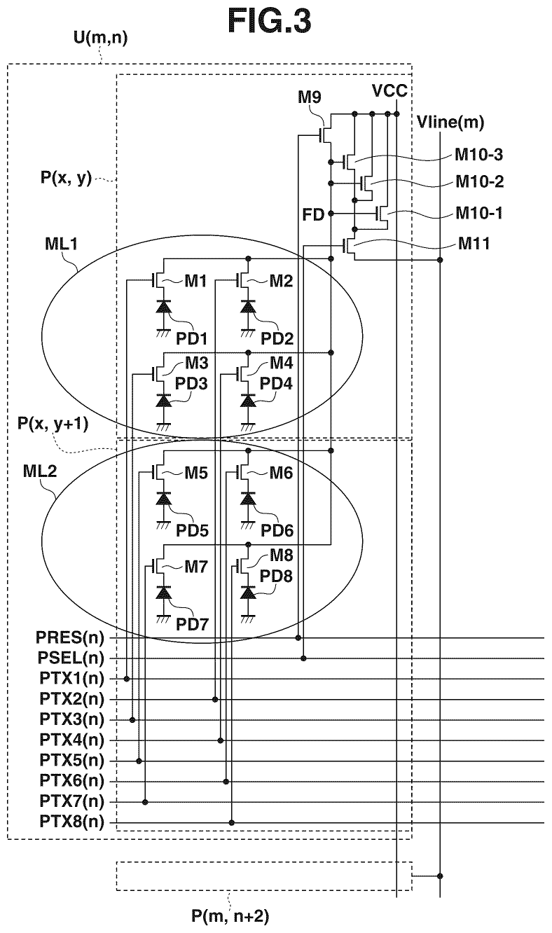

Each of the units U includes photoelectric conversion elements PD1 to PD8, a floating diffusion FD, transfer transistors M1 to M8, a reset transistor M9, an amplification transistor M10, and a selection transistor M11. In the unit U, the eight photoelectric conversion elements PD1 to PD8 share one floating diffusion FD. In FIG. 2, the one amplification transistor M10 is provided with respect to two pixels. However, as illustrated in FIG. 3, a plurality of amplification transistors M10-1, M10-2, and M10-3 may be arranged, and the number of amplification transistors is not limited to the above.

Each of the photoelectric conversion elements PD1 to PD8 photoelectrically converts incident light to generate and accumulate electric charges depending on the incident light. For example, each of the photoelectric conversion elements PD1 to PD8 is a photodiode. Anodes of the photodiodes constituting the photoelectric conversion elements PD1 to PD8 are connected to ground potential nodes. Cathodes of the photodiodes constituting the photoelectric conversion elements PD1 to PD8 are respectively connected to sources of the transfer transistors M1 to M8. In FIG. 3, although the one floating diffusion FD is shared by the eight photoelectric conversion elements PD1 to PD8, the present exemplary embodiment is not limited thereto. One floating diffusion FD may be arranged corresponding to one photoelectric conversion element PD, or one floating diffusion FD may be arranged for four photoelectric conversion elements PD.

Drains of the transfer transistors M1 to M8 are connected to the floating diffusion FD serving as a connection node between the source of the reset transistor M9 and the gate of the amplification transistor M10. The drain of the reset transistor M9 and the drain of the amplification transistor M10 are electrically connected to a power source line having a pixel power source potential VCC. The source of the amplification transistor M10 is connected to the drain of the selection transistor M11. The source of the selection transistor M11 is electrically connected to an electric current source (not illustrated) via a vertical output line Vline(m). With this configuration, the amplification transistor M10 and the electric current source operate as a source follower circuit. In other words, the amplification transistor M10 functions as an output unit capable of outputting a signal according to the potential of the floating diffusion FD to the vertical output line Vline(m). The floating diffusion FD includes a capacitance component (floating diffusion capacitance) which enables the floating diffusion FD to function as an electric charge retaining unit.

Control signals PTX1(n) to PTX8(n) are respectively input to the gates of the transfer transistors M1 to M8 from the vertical scanning circuit 102. The transfer transistors M1 to M8 respectively transfer electric charges accumulated in the photoelectric conversion elements PD1 to PD8 to the floating diffusion FD based on the control signals PTX1(n) to PTX8(n). In other words, each of the transfer transistors M1 to M8 functions as an electric charge transfer unit. The floating diffusion FD holds electric charges transferred thereto.

From the vertical scanning circuit 102, a control signal PRES(n) is input to the gate of the reset transistor M9. The reset transistor M9 resets the potential of the floating diffusion FD to a predetermined potential based on the control signal PRES(n).

From the vertical scanning circuit 102, a control signal PSEL(n) is input to the gate of the selection transistor M11. The control signal PSEL(n) is a signal for selecting a row from which the signals are to be output, so that the selection transistor M11 is brought into a conduction state or a non-conduction state based on the control signal PSEL(n). A trailing symbol “n” affixed to each of the control signals indicates a row number of the corresponding row.

The transistor is brought into a conduction state when a control signal input to the gate is at a high-level, and into a non-conduction state when the control signal is at a low-level. The high-level corresponds to a logical value “1”, whereas the low-level corresponds to a logical value “0”.

When the transfer transistors M1 to M8 are in non-conduction states, the photoelectric conversion elements PD1 to PD8 are brought into accumulation states, so that electric charges generated through the photoelectric conversion are accumulated. When the transfer transistors M1 to M8 as well as the reset transistor M9 are in conduction states, the photoelectric conversion elements PD1 to PD8 are brought into non-accumulation states, i.e., reset states, so that the electric charges are not accumulated. The pixel P(m, n) enters a read-out state when any of the transfer transistors M1 to M8 is in a conduction state, and the reset transistor M9 is in a non-conduction state. In this state, the electric charges accumulated in any of the photoelectric conversion elements PD1 to PD8 in the conduction state can be read out and transferred to the floating diffusion FD. In addition, a cathode of each of the photoelectric conversion elements PD1 to PD8 may electrically be connected to a power source line having power source potential, so that the photoelectric conversion elements PD1 to PD8 can be controlled and reset by an electric charge discharge transistor.

In the present exemplary embodiment, it is assumed that the respective transistors are N-channel metal-oxide semiconductor (MOS) transistors. However, the transistors can be P-channel MOS transistor. In such a case, levels of the respective control signals are changed as appropriate.

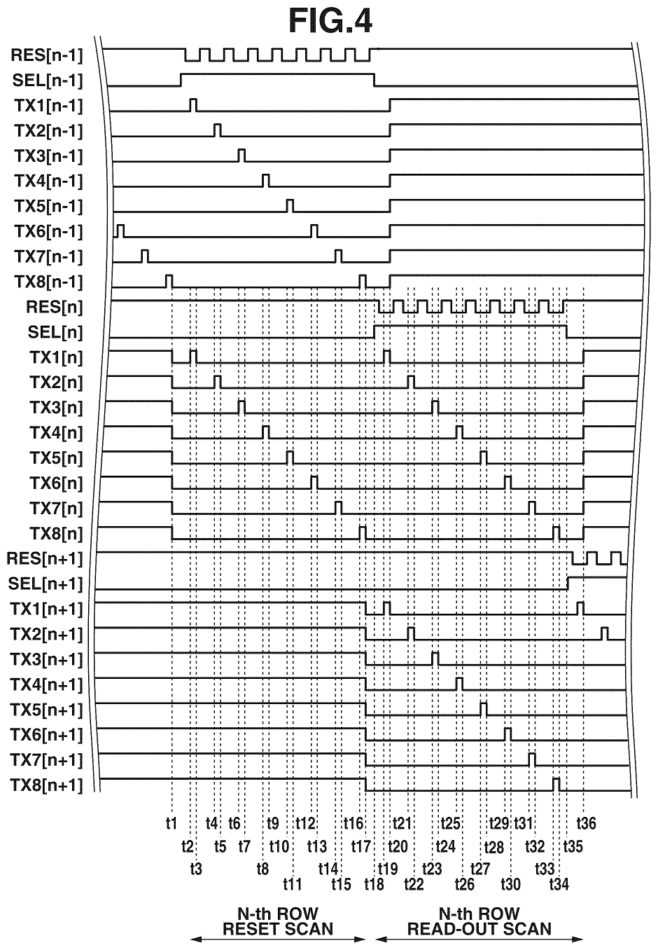

Next, a pixel drive pulse output from the vertical scanning circuit 102 will be described with reference to FIG. 4. FIG. 4 is a timing chart of control signals output from the vertical scanning circuit 102 according to the present exemplary embodiment. Timings of pixel drive pulses corresponding to pixels P for three rows including the (n−1)-th row, the n-th row, and the (n+1)-th row are extracted and illustrated in FIG. 4. Because the timings of the pixel drive pulses in the (n−1)-th row and the (n+1)-th row are simply shifted from the timings of the pixel drive pulses in the n-th row in the temporal direction, the pixel drive pulses in the n-th row is described below, and descriptions are omitted with respect to the pixel drive pulses in the other rows.

In a period before a time t1, the control signal RES[n] and the control signals TX1[n] to TX8[n] are maintained at high-levels. Therefore, the photoelectric conversion elements PD1 to PD8 are maintained in reset states. Further, the control signal SEL[n] is maintained at a low-level, so that the selection transistor M11 is in a non-conduction state.

At the time t1, the control signals TX1[n] to TX8[n] transition to low-levels. Thus, reset states of the photoelectric conversion elements PD1 to PD8 are released.

At a time t2, the control signal TX1[n] transitions to the high-level, so that the photoelectric conversion element to which the control signal TX1[n] is input is reset once. Thereafter, at a time t3, the control signal TX1[n] transitions to the low-level. Through the above operations, accumulation of electric charges is started at the photoelectric conversion element to which the control signal TX1[n] is input.

At a time t4, the control signal TX2[n] transitions to the high-level, so that the photoelectric conversion element to which the control signal TX2[n] is input is reset once. Thereafter, at a time t5, the control signal TX2[n] transitions to the low-level. Through the above operations, accumulation of electric charges is started at the photoelectric conversion element to which the control signal TX2[n] is input.

In a period from a time t6 to a time t17, pulses of the control signals TX3[n] to TX8[n] are output similarly, so that accumulation of electric charges is sequentially started at the corresponding photoelectric conversion elements. A series of operations in the period from the time t2 to the time t17 is referred to as “n-th row reset scan”.

In addition, a length of a period from the time t17 immediately after the n-th row reset scan to a time t18 when the next operation is started can be set as appropriate. By adjusting the length of this period, time spent on accumulating the electric charges in the photoelectric conversion elements PD1 to PD8 can be controlled. For example, a length of this period is set by a control signal output from the CPU 1. In FIG. 4, a period from the time t17 to the time t18 is adjusted to a substantially shortest period.

At the time t18, the control signal SEL[n] transitions to the high-level, so that the selection transistor M11 enters a conduction state. In this state, the amplification transistor M10 of the pixel P(m, n) is electrically connected to the vertical output line Vline m) via the selection transistor M11.

Through the above-described operations, a signal based on the potential of the floating diffusion FD can be output to the vertical output line Vline(m) in the m-th column.

At a time between the time t18 and a time t19, the control signal RES[n] transitions to the low-level. Therefore, a reset state of the floating diffusion FD is cancelled.

After the reset state of the floating diffusion FD is cancelled, the control signal TX1[n] transitions to the high-level at the time t19. Through the above-described operation, the electric charges accumulated in the photoelectric conversion element to which the control signal TX1[n] is input is transferred to the floating diffusion FD. A signal according to the potential of the floating diffusion FD is then output to the vertical output line Vline(m) in the m-th column. The signal output to the vertical output line Vline(m) is amplified and converted into a digital signal through analog-to-digital conversion by the column amplification circuit 103, and hold in a column memory.

Thereafter, at a time t20, the control signal TX1[n] transitions to the low-level. The transfer operation of the electric charges accumulated in the photoelectric conversion element is thereby completed. In other words, a period from the time t3 to the time t20 corresponds to an accumulation period of the electric charges in the photoelectric conversion element.

At a time between the time t20 and a time t21, the control signal RES[n] transitions to the high-level, and transitions to the low-level again after a predetermined time. Through the above operation, potential of the floating diffusion FD is reset.

At the time t21, the control signal TX2[n] transitions to the high-level, so that the transfer operation similar to the transfer operation executed at the time t19 is started. Thereafter, at a time t22, the control signal TX2[n] transitions to the low-level, so that the transfer operation of the electric charges accumulated in the photoelectric conversion element is completed.

In a period from a time t23 to a time t34, pulses of the control signals TX3[n] to TX8[n] are output similarly, so that the operation for transferring the electric charges to the floating diffusion FD from each of the photoelectric conversion elements is executed sequentially. The series of operations in the period from the time t19 to the time t34 is referred to as “n-th row read-out scan”.

At a time t35, the control signal SEL[n] transitions to the low-level, so that the selection transistor M11 enters a non-conduction state. The amplification transistor M10 of the pixel P is thereby electrically disconnected from the vertical output line Vline(m). At a time t36, the control signals TX1[n] to TX8[n] transition to the high-levels.

The photoelectric conversion elements PD1 to PD8 thereby enter reset states. As described above, a series of operations from the start of the accumulation of electric charges in the unit U in the n-th row to the end of the n-th row read-out scan is completed.

In the present exemplary embodiment, the operation for reading out the signal charges from the photoelectric conversion elements PD1 to PD8 one by one by individually controlling the control signals TX1[n] to TX8[n] has been described. However, the present exemplary embodiment is not limited to this operation.

For example, in a case where focus detection is to be executed while focusing on the vertical direction of the subject, signals may simultaneously be read out from the photoelectric conversion elements PD arranged adjacent to each other in a row direction. In other words, the control signal TX1[n] may be synchronized with the control signal TX3[n], and the control signal TX2[n] may be synchronized with the control signal TX4[n]. In a case where focus detection is to be executed while focusing on the horizontal direction of the object, the control signal TX1[n] may be synchronized with the control signal TX2[n], and the control signal TX3[n] may be synchronized with the control signal TX4[n].

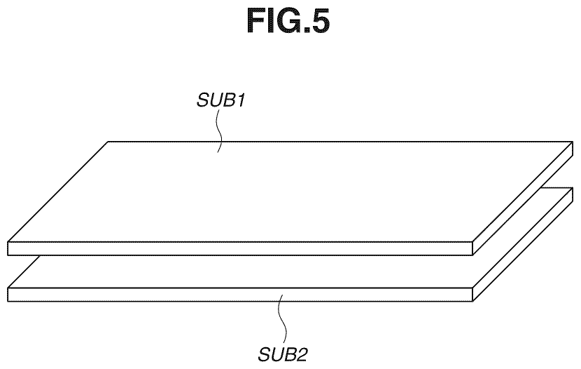

FIG. 5 is a diagram illustrating a configuration of the photoelectric conversion apparatus according to the present exemplary embodiment. The photoelectric conversion apparatus according to the present exemplary embodiment has a laminated sensor structure in which a first substrate SUB1 and a second substrate SUB2 serving as semiconductor substrates are laminated. Typically, the first substrate SUB1 is formed of monocrystal silicon. The second substrate SUB2 may also be formed of monocrystal silicon. However, the configuration is not limited to this example, and each of the first substrate SUB1 and the second substrate SUB2 may be a compound semiconductor substrate formed of a combination of a plurality of substances. In other words, the first substrate SUB1 and the second substrate SUB2 can be the semiconductor substrates of various types.

As to how the members illustrated in FIG. 1 are arranged on the first substrate SUB1 and the second substrate SUB2 can be changed as appropriate.

The present exemplary embodiment is also not limited to a laminated sensor. In other words, the present exemplary embodiment is also applicable to a back-face illumination type non-laminated sensor which includes the first substrate SUB1, on which all of the members illustrated in FIG. 1 are arranged, and the second substrate SUB2 as a supporting substrate.

The pixel array 101 illustrated in FIG. 1 is arranged on the first substrate SUB1. In contrast, of the constituent elements illustrated in FIG. 1, members other than the pixel array 101 are arranged on the second substrate SUB2. The first substrate SUB1 and the second substrate SUB2 can electrically be connected to each other through a known method. For example, a via structure having a metallic portion which penetrates the first substrate SUB1 may be arranged, and the wiring located between the first substrate SUB1 and the bonding face may be connected to the wiring located between the second substrate SUB2 and the bonding face through the via structure. This connection method is sometimes referred to as “Through Silicon Via (TSV)”. As another connection method, an exposed metallic bonding portion is provided on an inner portion of an insulation film on a bonding face located on a side of the first substrate SUB1. This metallic bonding portion is connected to the wiring between the first substrate SUB1 and the bonding face. Similarly, an exposed metallic bonding portion is provided on an inner portion of an insulation film on a bonding face located on a side of the second substrate SUB2. This metallic bonding portion is connected to the wiring between the second substrate SUB2 and the bonding face. The metallic bonding portion and the insulation film arranged on the bonding face on the side of the first substrate SUB1 are respectively bonded to the metallic bonding portion and the insulation film arranged on the bonding face on the side of the second substrate SUB2. In this way, the wiring between the first substrate SUB1 and the bonding face can electrically be connected to the wiring between the second substrate SUB2 and the bonding face. This bonding method is sometimes referred to as a hybrid bonding method.

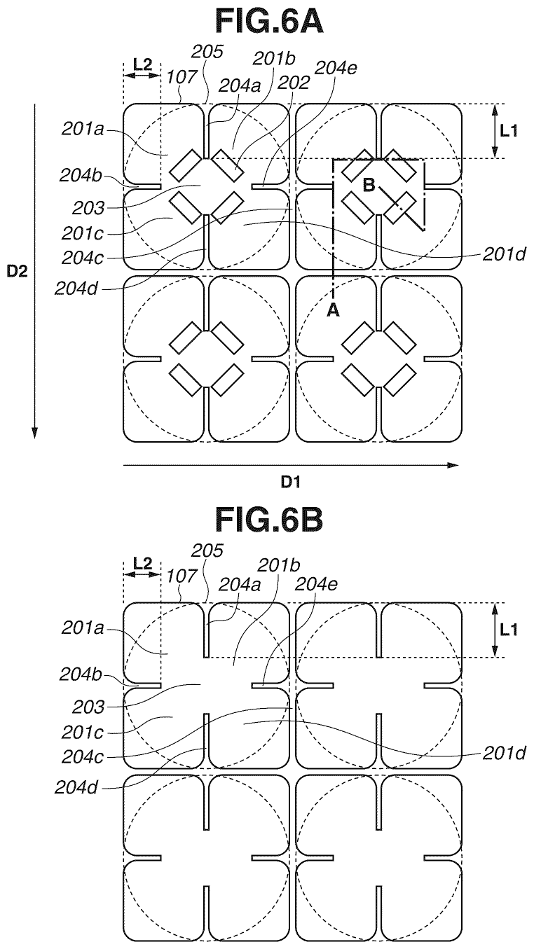

FIGS. 6A and 6B are plan views illustrating examples of the pixel 107. FIG. 6B is a plan view of the semiconductor substrate. FIG. 6A is a plan view illustrating a transfer gate 202 disposed on the semiconductor substrate in FIG. 6B. The pixel 107 includes four photoelectric conversion elements 201a to 201d, and the photoelectric conversion elements 201a to 201d are arranged on the semiconductor substrate. The semiconductor substrate has a first face serving as a light incident face and a second face opposite to the first face. FIG. 6A is a plan view viewed from a side of the second face. In order to clearly illustrate a positional relationships with the photoelectric conversion elements 201a to 201d, the microlens 205 is expressed by a dashed line, although the microlens 205 is also arranged on the second face.

As illustrated in FIGS. 6A and 6B, a plurality of photoelectric conversion elements 201a, 201b, 201c, and 201d is disposed on the pixel 107, so as to share one microlens 205. The photoelectric conversion elements 201a, 201b, 201c, and 201d are expressed as photoelectric conversion elements 201 when the photoelectric conversion elements 201a to 201d are generally described.

The photoelectric conversion elements 201a (first photoelectric conversion element) and 201b (second photoelectric conversion element) are sequentially arranged in a first direction D1, and the photoelectric conversion elements 201c (third photoelectric conversion element) and 202d (fourth photoelectric conversion element) are sequentially arranged in the first direction D1. The photoelectric conversion elements 201a and 201c are also sequentially arranged in a second direction D2, and the photoelectric conversion elements 201b and 201d are sequentially arranged in the second direction D2.

Each of the photoelectric conversion elements 201a to 201d may be a photodiode, and includes at least a semiconductor region of a first conductive type (i.e., first semiconductor region) which accumulates signal charges.

In FIG. 6A, a transfer gate 202 is disposed for each of the photoelectric conversion elements 201 (201a to 201d). On a side of the second face of the semiconductor substrate in a planar view, a floating diffusion (FD) portion 203 and element isolation regions 204a, 204b, 204c, 204d, and 204e are arranged between the plurality of photoelectric conversion elements 201.

The floating diffusion portion 203 is disposed at a position between the photoelectric conversion elements 201a and 201b, which is also a position between the photoelectric conversion elements 201b and 201c. For example, the floating diffusion portion 203 is formed of an N-type semiconductor region capable of accumulating signal charges, and is shared by the photoelectric conversion elements 201a to 201d.

Each of the transfer gates 202 is arranged adjacent to the floating diffusion portion 203, and transfers the signal charges output from the corresponding photoelectric conversion elements 201 to the floating diffusion portion 203. Each of the transfer gates 202 can be a horizontal (planar) transfer gate arranged on top of the second face of the semiconductor substrate, or can be a vertical transfer gate. A part of the vertical transfer gate penetrates the semiconductor substrate in a depth direction. In other words, the vertical transfer gate is arranged to extend toward the second face from the first face of the semiconductor substrate. The floating diffusion portion 203 is arranged at a depth different from a depth the electric charge accumulation regions of the photoelectric conversion elements 201 are arranged. In such a case, signal charges can be transferred to the floating diffusion portion 203 from the photoelectric conversion elements 201 arranged at a deep position by using the vertical transfer gates.

The photoelectric conversion elements 201 are isolated by element isolation regions 204 (204a to 204e). The element isolation region (first element isolation region) 204c including a trench structure penetrating to the second face from the first face of the semiconductor substrate is arranged between the photoelectric conversion elements 201 included in the first pixel 107 and the photoelectric conversion elements 201 included in the second pixel 107. The first pixel 107 receives light via the first microlens 205, and the second pixel 107 receives light via the second microlens 205. In one pixel 107, the photoelectric conversion elements 201a and 201b are isolated by the element isolation region (second element isolation region) 204a. The photoelectric conversion elements 201c and 201d are isolated by the element isolation region (fourth element isolation region) 204d. The photoelectric conversion elements 201a and 201c are also isolated by the element isolation region (third element isolation region) 204b. The photoelectric conversion elements 201b and 201d are isolated by the element isolation region (fifth element isolation region) 204e. In the present exemplary embodiment, the element isolation regions 204a and 204d are formed and arranged in a similar manner, and the element isolation regions 204b and 204e are formed and arranged in a similar manner. The trench structure in the element isolation region 204c does not have to penetrate to the second face from the first face, and the trench structure may partially be formed on the semiconductor substrate as long as the potential with respect to signal charges becomes higher than the potential in the element isolation regions 204a, 204b, 204d, and 204e within the pixel 107.

In the present exemplary embodiment, each of the element isolation regions 204a and 204b includes a trench structure.

For example, at least any one of an insulator or a metal is arranged on the trench structure. Each of the element isolation regions 204a and 204b may also include an isolation region consisting of a semiconductor region of a conductive type (second conductive type) different from a conductive type of the electric charge accumulation region of the photoelectric conversion element 201. For example, each of the element isolation regions 204a and 204b may include a P-type semiconductor region.

In the present exemplary embodiment, a length L1 in the second direction D2 of the trench structure in the element isolation region 204a is longer than a length L2 in the first direction D1 of the trench structure in the element isolation region 204b. In FIG. 6A, the trench structure between the photoelectric conversion elements 201 arranged in a horizontal direction extends to a position close to the floating diffusion portion 203 when compared to the trench structure between the photoelectric conversion elements 201 arranged in a vertical direction.

As described above, in a case where high-illuminance light is incident on the photoelectric conversion element 201a to cause signal charges to flow out, it is possible to make the flowing signal charges easily flow into the photoelectric conversion element 201c by changing the length L1 of the element isolation region 204a and the length L2 of the element isolation region 204b. In other words, it is possible to make the signal charges flow out in a specific direction within the pixel 107. Therefore, potential levels can be changed with respect to the signal charges between the photoelectric conversion elements 201 within the pixel 107.

In the present exemplary embodiment, the length L2 is shortened, so that potential levels with respect to the signal charges between the photoelectric conversion elements 201a and 201c arranged in the second direction D2 become lower than potential levels with respect to the signal charges between the photoelectric conversion elements 201a and 201b arranged in the first direction D1. This enables the signal charges to easily flow into the photoelectric conversion element 201c. In this way, accuracy of phase difference detection can be improved with respect to an object having a vertically-striped contrast.

In one embodiment, a difference between the length L1 and the length L2 is 5% or more, and 10% or more in another embodiment. With this configuration, a path through which the signal charges flow out can be created easily. For example, the length L1 can be 5% or more and 40% or less with respect to the size of the pixel 107. The length L2 can be, for example, 5% or more and 40% or less with respect to the size of the pixel 107.

In the present exemplary embodiment, the trench structure in the element isolation region 204a, the trench structure in the element isolation region 204b, and the trench structure in the element isolation region 204c are arranged continuously and integrally. However, the present exemplary embodiment is not limited thereto. For example, the trench structure in the element isolation region 204a, the trench structure in the element isolation region 204b, and the trench structure in the element isolation region 204c may be arranged discontinuously.

In FIG. 6A, the four photoelectric conversion elements 201 are arranged with respect to one pixel 107. However, the number of photoelectric conversion elements 201 does not have to be four. Similarly to the photoelectric conversion elements 201, four transfer gates 202 are arranged with respect to one pixel 107 as illustrated in FIG. 2. However, the number of transfer gates 202 does not have to be four, and can be more than four.

Color filters may be arranged between the microlenses 205 and the semiconductor substrate.

The color filters can be arranged in a Bayer array. The Bayer array may be formed by arranging color filters of different colors on the pixels 107, or by arranging color filters of the same color on the pixels 107 arrayed in a 2-by-2 matrix. For example, a red color filter is disposed between the pixel 107 and the microlens 205a, and a green color filter is disposed between the pixel 107 and the microlens 205b. Alternatively, a green color filter is disposed between the pixel 107 and the microlens 205c, and a blue color filter may be disposed between the pixel 107 and the microlens 205d. Instead of disposing the color filter of a different color on each of the pixels 107, green color filters may be disposed on the pixels 107 arrayed in a 2-by-2 matrix, and red color filters may be disposed on the pixels 107 arrayed in another 2-by-2 matrix adjacent to that 2-by-2 matrix. Then, blue color filters may be disposed on the pixels 107 arrayed in a 2-by-2 matrix, and green color filters may be disposed on the pixels 107 arrayed in another 2-by-2 matrix adjacent to that 2-by-2 matrix. Color filters of the same color may also be arranged on a plurality of pixels 107. The color filter may also not be arranged on the pixel 107.

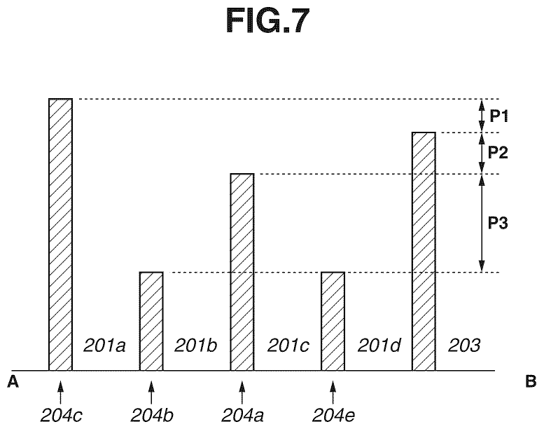

FIG. 7 illustrates potential levels with respect to signal charges in a region indicated by a line A-B in FIG. 6A. A potential difference PI indicates a difference between the potential with respect to the signal charges in the element isolation region 204c and the potential with respect to the signal charges in a region between the photoelectric conversion element 201 and the floating diffusion portion 203. A potential difference P2 indicates a difference between the potential with respect to the signal charges in the region between the photoelectric conversion element 201 and the floating diffusion portion 203 and the potential with respect to the signal charges in a region between the photoelectric conversion elements 201 within the same pixel 107. A potential difference P3 indicates a difference between the potential with respect to the signal charges in the region between the photoelectric conversion elements 201 within the same pixel 107 and the potential with respect to the signal charges in a region between the photoelectric conversion elements 201a and 201b.

Because of the potential difference P1, surplus signal charges generated in the photoelectric conversion elements 201 within one pixel 107 can be prevented from flowing into the adjacent pixel 107 without being discharged to the floating diffusion portion 203. It is thereby possible to suppress worsening of blooming. Because of the potential difference P2, the signal charges accumulated in the photoelectric conversion elements 201 can easily be discharged to the floating diffusion portion 203 instead of being discharged to the adjacent pixel 107. It is thereby possible to suppress worsening of linearity under high illuminance. According to the present exemplary embodiment, the potential difference P3 can also be increased. In a case where the potential difference P3 is small, signal charges accumulated in the photoelectric conversion elements 201 flow into the other photoelectric conversion elements 201 when phase difference detection is executed. Thus, output of the photoelectric conversion elements 201 is worsened under high illuminance when phase difference detection is executed. On the other hand, according to the present exemplary embodiment, the potential difference P3 can be ensured, and therefore it is possible to make signal charges flow out between the photoelectric conversion elements 201 on which phase difference detection is executed. Thus, phase difference detection can be executed by acquiring appropriate signals.

In a case where a total of the signal charges generated in a plurality of photoelectric conversion elements 201 is used as a photoelectric conversion signal, there is a risk that linearity of pixel output characteristics is worsened when an object is captured under high illuminance. For this reason, the photoelectric conversion apparatus has a potential structure that enables signal charges to leak between the plurality of photoelectric conversion elements 201 within the pixel 107 in a case where the photoelectric conversion elements 201 are saturated with signal charges. In this way, a part of the signal charges discharged to the floating diffusion portion 203 leak to the adjacent photoelectric conversion element 201, so that worsening of linearity of the pixel output characteristics can be suppressed when image capturing is executed under high illuminance. However, in a case where the plurality of photoelectric conversion elements 201 within the pixel 107 is saturated with signal charges to cause the signal charges to leak in various directions, accuracy of the phase difference detection may be degraded.

In the present exemplary embodiment, the photoelectric conversion apparatus has a potential structure for providing a direction in which the signal charges can easily leak and a direction in which the signal charges cannot easily leak between the plurality of photoelectric conversion elements 201 within the pixel 107. In a case where the pixel 107 includes a plurality of photoelectric conversion elements 201 that share one microlens 205, signal output of each of the photoelectric conversion elements 201 is processed in order to detect a phase difference. At the same time, the signal output of each of the photoelectric conversion elements 201 is processed as a signal to be used for image capturing. At this time, the signal used for image capturing is processed as one pixel signal by adding up the signal charges photoelectrically converted by the plurality of photoelectric conversion elements 201 that share one microlens 205, from the viewpoints of reduction of photon shot noise with respect to the signal amount and a read-out speed. Even in a case where only the signal charges generated in one photoelectric conversion element 201 have reached a saturated electric charge amount, surplus signal charges leak out, so that the surplus signal charges are accumulated in another photoelectric conversion element 201 on which phase detection is executed. It is therefore possible to suppress degradation of accuracy of the phase difference detection.

In addition, a length of the trench structure in the element isolation region 204a can be longer than a length of the trench structure in the element isolation region 204b. The relationship between the length of the trench structure in the element isolation region 204a and the length of the trench structure in the element isolation region 204b may also be changed for each of the pixels 107.

In FIGS. 6A and 6B, the length of the trench structure in the element isolation region 204e is longer than the length of the trench structure in the element isolation region 204d. However, the lengths of the trench structures in the element isolation regions 204d and 204e can also be the same.

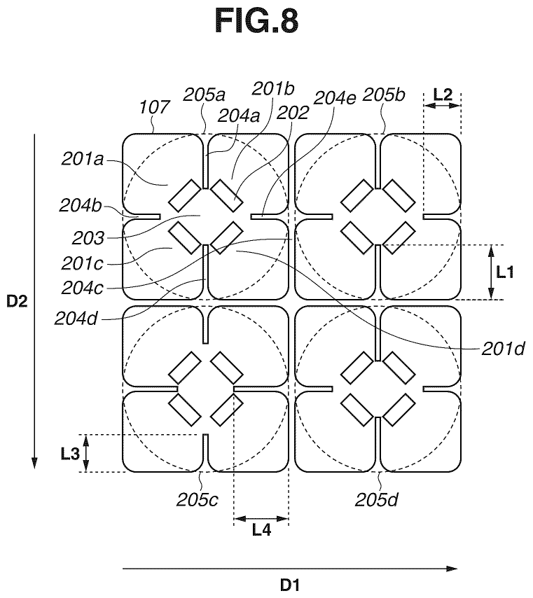

A configuration of the photoelectric conversion apparatus according to a first variation example of the first exemplary embodiment will now be described with reference to FIG. 8.

The same reference numerals are applied to constituent elements similar to those described in the first exemplary embodiment, and descriptions of these constituent elements may be omitted or simplified. Similarly to FIG. 6A, FIG. 8 is a plan view viewed from a side of the second face of the semiconductor substrate.

In FIG. 8, with respect to one pixel 107 (first pixel) from among four pixels 107 arrayed in a 2-by-2 matrix, a length L1 in the second direction D2 of the trench structure in the element isolation region 204a is longer than a length L2 in the first direction D1 of the trench structure in the element isolation region 204b. With respect to another pixel 107 (third pixel) different from the one pixel 107 from among the four pixels 107, a length L3 in the second direction D2 of the trench structure in the element isolation region 204a is shorter than a length L4 in the first direction D1 of the trench structure in the element isolation region 204b.

In the present exemplary embodiment, the length L1 and the length L4 are the same, and the length L2 and the length L3 are the same. However, the present exemplary embodiment is not limited to the above, and the length L1 and the length L4 may be different, and the length L2 and the length L3 may be different.

For example, in a case where color filters of a same color are arranged on one pixel 107 and another pixel 107, accuracy of phase difference detection can be increased with respect to the object having a vertically-striped contrast at one of the pixels 107. Then, accuracy of phase difference detection can be increased with respect to the object having a horizontally-striped contrast at the other pixel 107. According to the first variation example, it is thus possible to improve the accuracy of phase difference detection with respect to the object having the vertically-striped contrast as well as the object having the horizontally-striped contrast. The lengths L3 and L4 are also applicable to the pixels 107 on which color filters of different colors are arranged.

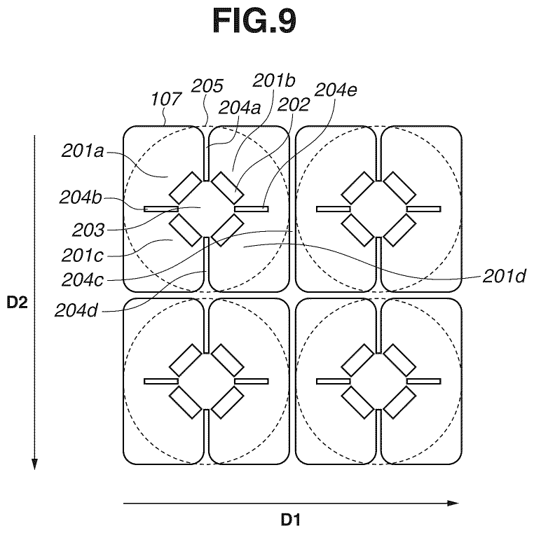

A configuration of the photoelectric conversion apparatus according to a second variation example of the first exemplary embodiment will be described with reference to FIG. 9.

The same reference numerals are applied to constituent elements similar to those described in the first exemplary embodiment, and descriptions of these constituent elements may be omitted or simplified. Similarly to FIG. 6A, FIG. 9 is a plan view viewed from a side of the second face of the semiconductor substrate.

In the photoelectric conversion apparatus according to the second variation example, the trench structure in the element isolation region 204a and the trench structure in the element isolation region 204c are connected, and the trench structure in the element isolation region 204b and the trench structure in the element isolation region 204c are not connected.

According to the second variation example, it is possible to make surplus signal charges leak in a region away from the floating diffusion portion 203. It is therefore possible to easily reduce surplus signal charges entering the floating diffusion portion 203, so that linearity under high illuminance can easily be improved.

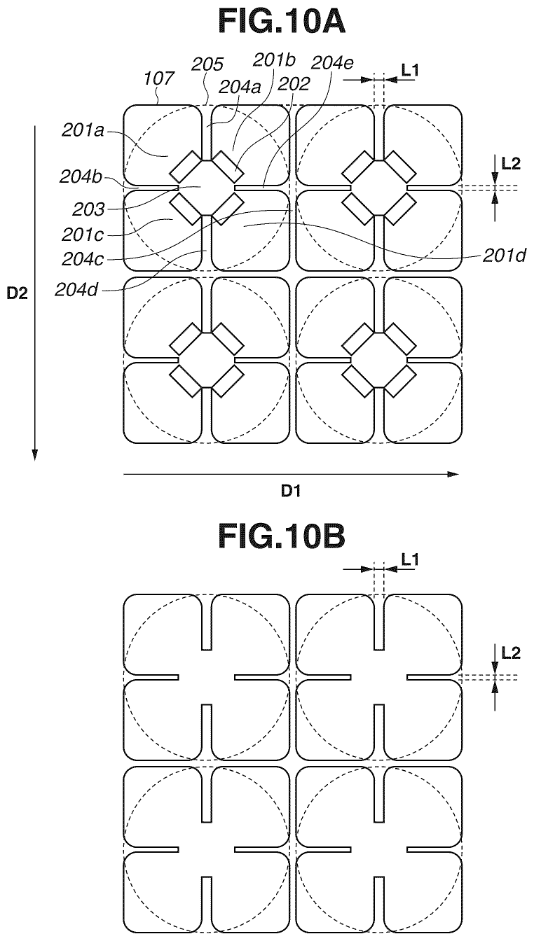

A configuration of the photoelectric conversion apparatus according to a second exemplary embodiment of the disclosure will be described with reference to FIGS. 10A and 10B.

FIGS. 10A and 10B are plan views viewed from a side of the second face of the semiconductor substrate similarly to FIGS. 6A and 6B. The same reference numerals are applied to constituent elements similar to those described in the first exemplary embodiment, and descriptions of these constituent elements may be omitted or simplified. The present exemplary embodiment is substantially the same as the first exemplary embodiment except for the points described below. Thus, descriptions thereof will be omitted.

The present exemplary embodiment is different from the first exemplary embodiment in that the trench structure in the element isolation region 204a and the trench structure in the element isolation region 204b have different widths. The trench structure in the element isolation region 204a has a length L1 in the first direction D1, and the trench structure in the element isolation region 204b has a length L2 in the second direction D2. The length L1 is longer than the length L2 (L1>L2).

According to the present exemplary embodiment, it is possible to make a level of potential with respect to the signal charges in the element isolation region 204a in the horizontal direction be larger than a level of potential with respect to the signal charges in the element isolation region 204b in the vertical direction similarly to the first exemplary embodiment. In this way, accuracy of phase difference detection can be increased with respect to the subject having a vertically-striped contrast.

In FIG. 10A, the width of the trench structure in the element isolation region 204a is wider than the width of the trench structure in the element isolation region 204b. However, the width of the trench structure in the element isolation region 204a can be narrower than the width of the trench structure in the element isolation region 204b. Further, a relationship between the width of the trench structure in the element isolation region 204a and the width of the trench structure in the element isolation region 204b may also be changed for each of the pixels 107. The width of the trench structure in the element isolation region 204a may also be the same as the width of the trench structure in the element isolation region 204b.

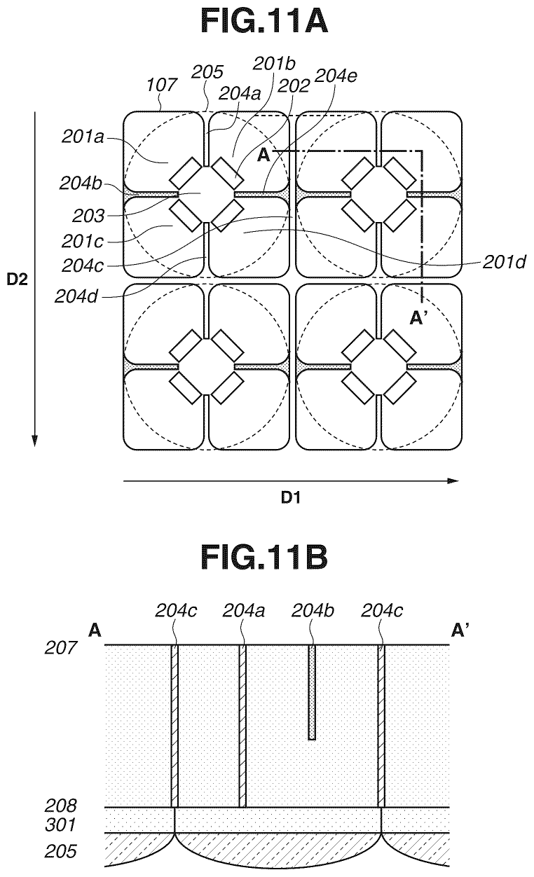

A configuration of the photoelectric conversion apparatus according to a third exemplary embodiment of the disclosure will now be described with reference to FIGS. 11A and 11B. FIG. 11A is a plan view viewed from a side of the second face of the semiconductor substrate. FIG. 11B is a diagram illustrating an example of a cross sectional face of the pixel 107 taken along a line A-A′ in FIG. 11A. The same reference numerals are applied to constituent elements similar to those described in the first exemplary embodiment, and descriptions of these constituent elements may be omitted or simplified. The present exemplary embodiment is also substantially the same as the first exemplary embodiment except for the points described below, and thus descriptions thereof are omitted.

According to the present exemplary embodiment, in the element isolation region 204b and the element isolation region 204a, a depth of one trench structure is different from a depth of another trench structure. For example, the present exemplary embodiment is different from the first exemplary embodiment in that a depth of the trench structure in the element isolation region 204b is less than a depth of the trench structure in the element isolation region 204a. The trench structure in the element isolation region 204b is also formed from a side of the second face 207 of the semiconductor substrate.

For example, the trench structure in the element isolation region 204a penetrates the semiconductor substrate, whereas the trench structure in the element isolation region 204b does not penetrate the semiconductor substrate. For example, in one embodiment, the trench structure in the element isolation region 204b is formed within a range of ½ or more and 1/20 or less of the thickness of the semiconductor substrate.

According to the present exemplary embodiment, a path through which signal charges easily leak and a path through which signal charges cannot easily leak can be provided between the plurality of photoelectric conversion elements 201, so that it is possible to increase the accuracy of phase difference detection. Since the trench structure can be formed on a side away from the microlens 205, lowering of sensitivity caused by light incident on the trench structure can be suppressed.

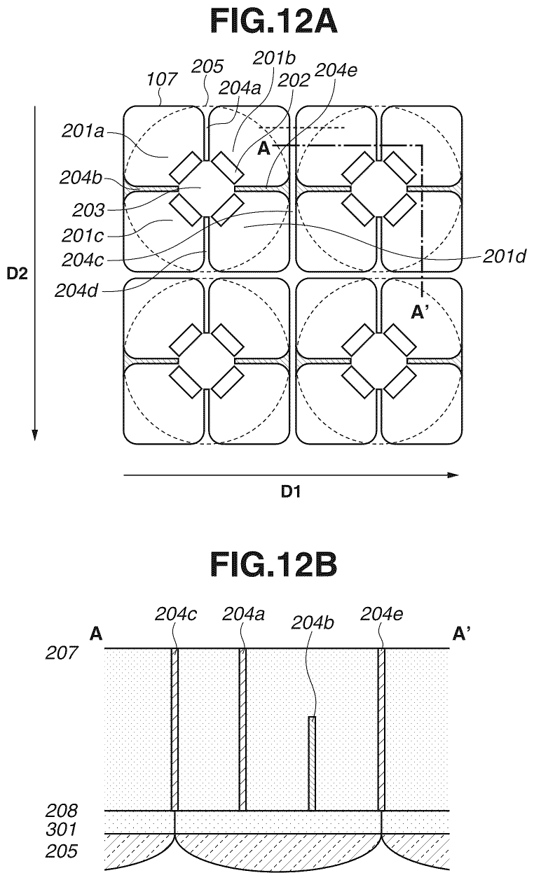

A configuration of the photoelectric conversion apparatus according to a variation example of the third exemplary embodiment will now be described with reference to FIGS. 12A and 12B. FIG. 12A is a plan view viewed from a side of the second face of the semiconductor substrate. FIG. 12B is a diagram illustrating an example of a cross sectional face of the pixel 107 taken along a line A-A′ in FIG. 12A.

In the variation example, the trench structure in the element isolation region 204b is formed from a side of the first face 208. According to the variation example, the trench structures between the photoelectric conversion elements 201 within the pixel 107 are formed on a side close to the second face 207.

According to the present exemplary embodiment, the trench structure in the element isolation region 204b is formed at a position away from a side of the first face 208 of the semiconductor substrate. Therefore, it is possible to easily design the potential of each of the photoelectric conversion elements 201.

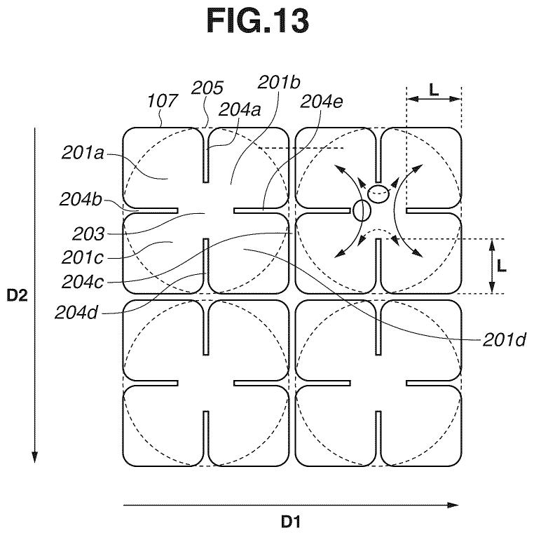

A configuration of the photoelectric conversion apparatus according to a fourth exemplary embodiment of the disclosure will now be described with reference to FIGS. 13 to 15. The same reference numerals are applied to constituent elements similar to those described in the first to the third exemplary embodiments, and descriptions of these constituent elements may be omitted or simplified.

FIG. 13 is diagram illustrating a concept of the present exemplary embodiment. In the present exemplary embodiment, the trench structure in the element isolation region 204a is the same as the trench structure in the element isolation region 204b. In other words, the trench structures between the photoelectric conversion elements 201 within the pixel 107 have the same width and length. In the present exemplary embodiment, easiness of signal charge leakage in the horizontal direction and easiness of signal charge leakage in the vertical direction are changed by controlling implantation of the semiconductor region of a conductive type different from that of signal charges in the semiconductor substrate. For example, in FIG. 13, signal charge leakage occurs more easily between the photoelectric conversion elements 201 arranged in the vertical direction than in the photoelectric conversion elements 201 arrayed in the horizontal direction.

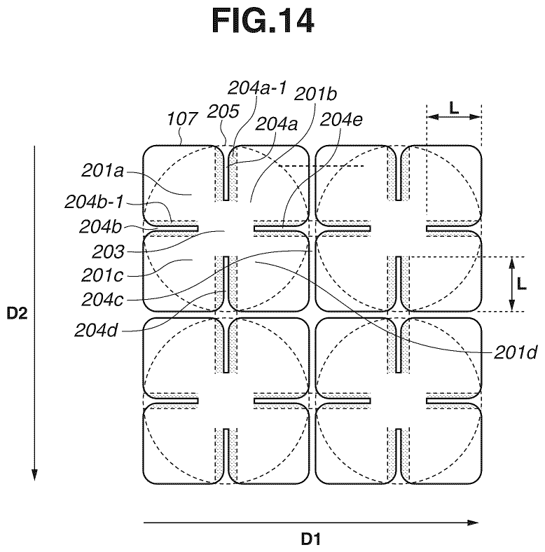

FIG. 14 is a plan view viewed from a side of the second face of the semiconductor substrate of pixels 107 according to the present exemplary embodiment. In the present exemplary embodiment, the element isolation region 204a includes a trench structure and a semiconductor region 204a-1 (second semiconductor region) of a conductive type different from that of signal charges. The element isolation region 204b includes a trench structure and a semiconductor region 204b-1 (third semiconductor region) of a conductive type different from that of signal charges. Then, a width of the semiconductor region 204a-1 is wider than a width of the semiconductor region 204b-1.

Through the configuration described in the present exemplary embodiment, it is possible to provide a path through which the signal charges easily leak and a path through which the signal charges cannot easily leak between the photoelectric conversion elements 201 within the pixel 107.

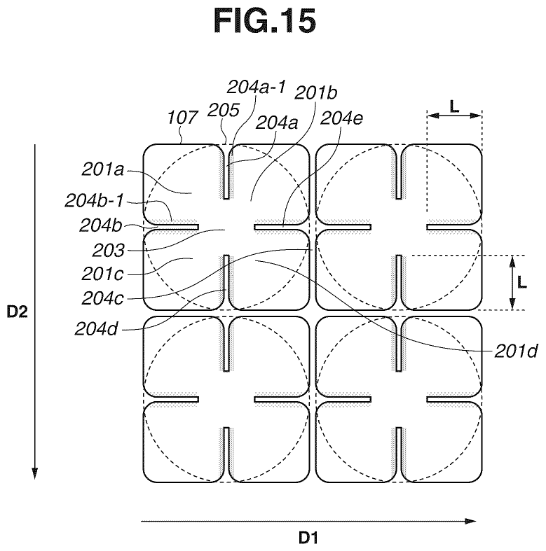

FIG. 15 is a diagram illustrating a variation example of the pixel 107 according to the present exemplary embodiment. In the present exemplary embodiment, the element isolation region 204a includes a trench structure and a semiconductor region 204a-1 (second semiconductor region) of a conductive type different from that of signal charges. The element isolation region 204b also includes a trench structure and a semiconductor region 204b-1 (third semiconductor region) of a conductive type different from that of signal charges. The element isolation region 204d includes a trench structure and a semiconductor region (fourth semiconductor region) of a conductive type different from that of signal charges. The element isolation region 204e includes a trench structure and a semiconductor region (fifth semiconductor region) of a conductive type different from that of signal charges. Then, an impurity concentration of the semiconductor region 204a-1 is higher than the impurity concentration of the semiconductor region 204b-1. With this configuration, it is also possible to provide a path through which signal charges easily leak and a path through which signal charges cannot easily leak between the photoelectric conversion elements 201 within the pixel 107.

For example, the impurity concentration of the semiconductor region 204a-1 can be set to 1E15 to 1E19 [/cm³], and the impurity concentration of the semiconductor region 204b-1 can be set to 1E15 to 1E19 [/cm³]. In one embodiment, the impurity concentration of the semiconductor region 204b-1 be ⅘ or less than the impurity concentration of the semiconductor region 204a-1.

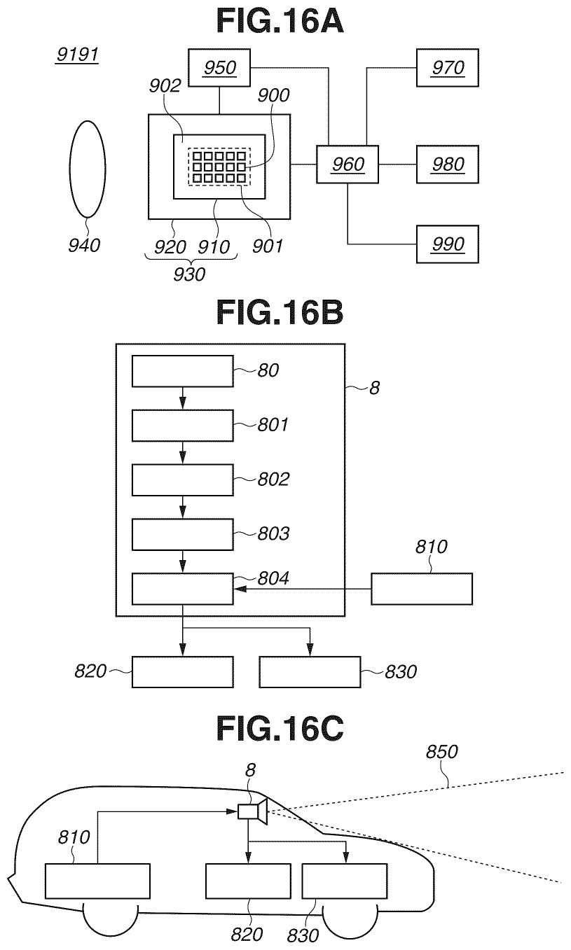

A fifth exemplary embodiment is applicable to any of the first to fourth exemplary embodiments. FIG. 16A is a schematic diagram illustrating an equipment 9191 including a semiconductor apparatus 930 according to the present exemplary embodiment. Any of the photoelectric conversion apparatuses according to the above-described exemplary embodiments can be used for the semiconductor apparatus 930. The equipment 9191 including the semiconductor apparatus 930 will now be described in detail. The semiconductor apparatus 930 can include a package 920 which houses a semiconductor device 910 as well as the semiconductor device 910. The package 920 can also include a base member to which the semiconductor device 910 is fixed and a cover member such as a glass cover facing the semiconductor device 910. The package 920 can further include bonding members such as bonding wire and bumps, which connect a terminal provided on the base member and a terminal arranged on the semiconductor device 910.

The equipment 9191 can include at least any one of an optical apparatus 940, a control apparatus 950, a processing apparatus 960, a display apparatus 970, a storage apparatus 980, or a mechanical apparatus 990. The optical apparatus 940 functions in association with the semiconductor apparatus 930. The optical apparatus 940 includes, for example, an optical system consisting of a lens, a shutter, and a mirror, which introduce light to the semiconductor apparatus 930. The control apparatus 950 controls the semiconductor apparatus 930. The control apparatus 950 is a semiconductor apparatus such as an application specific integration circuit (ASIC).

The processing apparatus 960 processes the signals output from the semiconductor apparatus 930. The processing apparatus 960 is a semiconductor apparatus such as a central processing unit (CPU) or an ASIC for constituting an analog front-end (AFE) or a digital front-end (DFE). The display apparatus 970 is an electroluminescence (EL) display apparatus or a liquid crystal display apparatus for displaying information (images) acquired by the semiconductor apparatus 930. The storage apparatus 980 is a magnetic device or a semiconductor device for storing information (images) acquired by the semiconductor apparatus 930. The storage apparatus 980 is a volatile memory such as a static random access memory (SRAM) or a dynamic RAM (DRAM), or a non-volatile memory such as a flash memory or a hard disk drive.

The mechanical apparatus 990 includes a movable unit or a propulsion unit such as a motor or an engine. The equipment 9191 displays a signal output from the semiconductor apparatus 930 on the display apparatus 970, or transmits the signal output from the semiconductor apparatus 930 to the outside through a communication apparatus (not illustrated) included in the equipment 9191. It is therefore the equipment 9191 further includes the storage apparatus 980 and the processing apparatus 960 separately from a storage circuit or a calculation circuit included in the semiconductor apparatus 930. The mechanical apparatus 990 may be controlled based on the signal output from the semiconductor apparatus 930.

The equipment 9191 is also appropriate to be used as electronic devices such as information terminals (e.g., a smartphone and a wearable terminal) having image capturing functions and cameras (e.g., an interchangeable-lens camera, a compact camera, a video camera, and a monitoring camera). The mechanical apparatus 990 operating in the camera can drive the components included in the optical apparatus 940 in order to perform zooming, focusing, or shutter operations. Alternatively, the mechanical apparatus 990 operating in the camera can move the semiconductor apparatus 930 in order to perform an anti-vibration operation.

The equipment 9191 can also be applied to transportation devices such as a vehicle, a ship, and an air vehicle. The mechanical apparatus 990 operating in a transportation device is used as a moving apparatus. The equipment 9191 operating as a transportation device is for transporting the semiconductor apparatus 930 or assisting and/or automating the operation (driving operation) through an image capturing function. The processing apparatus 960 for assisting and/or automating the operation (driving operation) can execute processing for operating the mechanical apparatus 990 serving as a moving apparatus based on the information acquired by the semiconductor apparatus 930. Alternatively, the equipment 9191 can be a medical device such as an endoscope, a measurement device such as a range-finding sensor, an analytical device such as an electronic microscope, an office machine such as a copying machine, or an industrial machine such as a robot.

According to the above-described exemplary embodiment, it is possible to acquire favorable pixel characteristics. Accordingly, it is possible to give added value to the semiconductor apparatus 930. The value addition described above corresponds to at least any of functional addition, performance improvement, characteristic improvement, reliability improvement, improvement in fabrication yield ratio, environmental load reduction, cost-cutting, downsizing, and weight reduction.

Accordingly, the equipment 9191 can also be upgraded if the semiconductor apparatus 930 according to the present exemplary embodiment is used for the device 9191. For example, excellent performance can be acquired by mounting the semiconductor apparatus 930 on the transportation device and capturing images outside the transportation device or measuring an external environment. Thus, mounting the semiconductor apparatus 930 according to the present exemplary embodiment on the transportation device is advantageous for upgrading the performance of the transportation device itself when the transportation device is to be manufactured and distributed. In particular, the semiconductor apparatus 930 is for the transportation device that assists and/or automates the operation of the transportation device by using the information acquired by the semiconductor apparatus 930.

A photoelectric conversion system and a moving body according to the present exemplary embodiment will be described with reference to FIGS. 16B and 16C.

FIG. 16B is a diagram illustrating an example of a photoelectric conversion system related to a car-mounted camera. A photoelectric conversion system 8 includes a photoelectric conversion apparatus 80. The photoelectric conversion apparatus 80 is the photoelectric conversion apparatus (image capturing apparatus) according to any one of the above-described exemplary embodiments. The photoelectric conversion system 8 includes an image processing unit 801 which executes image processing on a plurality of pieces of image data acquired by the photoelectric conversion apparatus 80 and a parallax acquisition unit 802 which calculates a parallax (a phase difference between parallax images) from the plurality of pieces of image data acquired by the photoelectric conversion system 8. The photoelectric conversion system 8 further includes a distance acquisition unit 803 which calculates a distance to a target object based on the calculated parallax and a collision determination unit 804 which determines a possibility of collision based on the calculated distance. Herein, the parallax acquisition unit 802 and the distance acquisition unit 803 are examples of a distance information acquisition unit which acquires information about a distance to a target object. The information about a distance is information related to a parallax, a defocus amount, and a distance to a target object. The collision determination unit 804 may determine the possibility of collision by using any of the above-described distance information. The distance information acquisition unit may be implemented by exclusively-designed hardware or a software module. Further, the distance information acquisition unit may be implemented by a field programmable gate array (FPGA), an application specific integrated circuit (ASIC), or a combination of the FPGA and the ASIC.

The photoelectric conversion system 8 is connected to a vehicle information acquisition apparatus 810, and can acquire vehicle information such as a vehicle speed, a yaw rate, and a rudder angle. The photoelectric conversion system 8 is connected to a control ECU (ECU: electronic control unit) 820. The control ECU 820 is a control apparatus which outputs a control signal for generating breaking power to the vehicle based on a determination result acquired by the collision determination unit 804. The photoelectric conversion system 8 is also connected to an alarming apparatus 830 which issues a warning to a driver based on a determination result acquired by the collision determination unit 804. For example, in a case where the collision determination unit 804 determines that a possibility of collision is high, the control ECU 820 executes vehicle control to avoid collision or to reduce damages by applying a brake, releasing a gas pedal, or suppressing an engine output. The alarming apparatus 830 issues a warning to the user by making an alarming sound, displaying alarming information on a screen of a car navigation system, or producing vibrations in a seat belt or a steering wheel.

In the present exemplary embodiment, peripheral views of a vehicle, e.g., a forward view and a backward view of the vehicle, are captured by the photoelectric conversion system 8.

FIG. 16C is a diagram illustrating the photoelectric conversion system 8 for capturing a forward view of a vehicle (i.e., image capturing range 850). The vehicle information acquisition apparatus 810 issues an instruction to the photoelectric conversion system 8 or the photoelectric conversion apparatus 80. Through the above-described configuration, it is possible to improve the range-finding accuracy.

In the above, the present exemplary embodiment is described with respect to the control for preventing a vehicle from colliding with another vehicle. However, the aspect of the embodiments is also applicable to control for automatically driving a vehicle while following another vehicle or control for automatically driving a vehicle without making the vehicle drift out of a traffic lane. The photoelectric conversion system 8 is also applicable not only to a vehicle such as an automobile, but also to a moving body (moving apparatus) such as a ship, an airplane, or an industrial robot. Furthermore, the photoelectric conversion system 8 is applicable not only to a moving body, but also to a device such as an intelligent transportation system (ITS), which widely employs an object recognition function.

The above-described exemplary embodiments can be modified as appropriate within a range not departing from the technical spirit of the disclosure. The contents of disclosure in the present specification documents include not only the contents explicitly described in the present specification documents but also all the respects that can be grasped from the present specification documents and drawings attached thereto. Further, the contents of disclosure of the present specification documents include a complement of the concept described in the present specification documents. In other words, if the present specification documents include a description “A is greater than B”, for example, this can be said that the present specification documents also disclose a description “A is not greater than B” even if the description “A is not greater than B” is omitted. This is because “A is greater than B” is described based on the premise that the case where “A is not greater than B” is taken into consideration.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-021763, filed Feb. 16, 2024, which is hereby incorporated by reference herein in its entirety.

What is claimed is:

1. An apparatus comprising a first pixel configured to receive light via a first microlens and a second pixel configured to receive light via a second microlens,
wherein each of the first pixel and the second pixel is disposed on a semiconductor substrate having a first face and a second face opposite to the first face, and includes a first photoelectric conversion element and a second photoelectric conversion element that are sequentially arranged in a first direction, a third photoelectric conversion element and a fourth photoelectric conversion element that are sequentially arranged in the first direction, and a floating diffusion portion shared by the first photoelectric conversion element, the second photoelectric conversion element, the third photoelectric conversion element, and the fourth photoelectric conversion element,
wherein the first photoelectric conversion element and the third photoelectric conversion element are sequentially arranged in a second direction intersecting with the first direction, and the second photoelectric conversion element and the fourth photoelectric conversion element are sequentially arranged in the second direction,
wherein the floating diffusion portion is disposed between the first photoelectric conversion element and the fourth photoelectric conversion element and between the second photoelectric conversion element and the third photoelectric conversion element,
wherein a first element isolation region including a trench structure is disposed between the first pixel and the second pixel,
wherein, in the first pixel, a second element isolation region including a trench structure is disposed between the first photoelectric conversion element and the second photoelectric conversion element, and a third element isolation region including a trench structure is disposed between the first photoelectric conversion element and the third photoelectric conversion element, and
wherein, in a planar view of the first face, a length in the first direction of the trench structure in the second element isolation region is larger than a length in the second direction of the trench structure in the third element isolation region.

2. An apparatus comprising a first pixel configured to receive light via a first microlens and a second pixel configured to receive light via a second microlens,
wherein each of the first pixel and the second pixel is disposed on a semiconductor substrate having a first face and a second face opposite to the first face, and includes a first photoelectric conversion element and a second photoelectric conversion element sequentially arranged in a first direction, a third photoelectric conversion element and a fourth photoelectric conversion element sequentially arranged in the first direction, and a floating diffusion portion shared by the first photoelectric conversion element, the second photoelectric conversion element, the third photoelectric conversion element, and the fourth photoelectric conversion element,
wherein the first photoelectric conversion element and the third photoelectric conversion element are sequentially arranged in a second direction intersecting with the first direction, and the second photoelectric conversion element and the fourth photoelectric conversion element are sequentially arranged in the second direction,
wherein the floating diffusion portion is disposed between the first photoelectric conversion element and the fourth photoelectric conversion element and between the second photoelectric conversion element and the third photoelectric conversion element,
wherein a first element isolation region including a trench structure is disposed between the first pixel and the second pixel,
wherein, in the first pixel, a second element isolation region including a trench structure is disposed between the first photoelectric conversion element and the second photoelectric conversion element, and a third element isolation region including a trench structure is disposed between the first photoelectric conversion element and the third photoelectric conversion element,
wherein, in a planar view of the first face, an area of the trench structure in the second element isolation region is different from an area of the trench structure in the third element isolation region, and
wherein a difference between the area of the trench structure in the second element isolation region and the area of the trench structure in the third element isolation region is 5% or more.

3. An apparatus comprising a first pixel configured to receive light via a first microlens and a second pixel configured to receive light via a second microlens,
wherein each of the first pixel and the second pixel are arranged on a semiconductor substrate having a first face and a second face opposite to the first face, and includes a first photoelectric conversion element and a second photoelectric conversion element sequentially arranged in a first direction, a third photoelectric conversion element and a fourth photoelectric conversion element sequentially arranged in the first direction, and a floating diffusion portion shared by the first photoelectric conversion element, the second photoelectric conversion element, the third photoelectric conversion element, and the fourth photoelectric conversion element,
wherein the first photoelectric conversion element and the third photoelectric conversion element are sequentially arranged in a second direction intersecting with the first direction, and the second photoelectric conversion element and the fourth photoelectric conversion element are sequentially arranged in the second direction,
wherein the floating diffusion portion is disposed between the first photoelectric conversion element and the fourth photoelectric conversion element and between the second photoelectric conversion element and the third photoelectric conversion element,
wherein a first element isolation region including a trench structure is disposed between the first pixel and the second pixel,
wherein, in the first pixel, a second element isolation region including a trench structure is disposed between the first photoelectric conversion element and the second photoelectric conversion element, and a third element isolation region including a trench structure is disposed between the first photoelectric conversion element and the third photoelectric conversion element,
wherein each of the first photoelectric conversion element, the second photoelectric conversion element, the third photoelectric conversion element, and the fourth photoelectric conversion element includes a first semiconductor region of a first conductive-type configured to accumulate signal charges, and
wherein, in a planar view of the first face, a length in the first direction of a second semiconductor region of a second conductive-type disposed adjacent to the trench structure in the second element isolation region is larger than a length in the second direction of a third semiconductor region of the second conductive-type disposed adjacent to the trench structure in the third element isolation region.

4. An apparatus comprising a first pixel configured to receive light via a first microlens and a second pixel configured to receive light via a second microlens,
wherein each of the first pixel and the second pixel are arranged on a semiconductor substrate having a first face and a second face opposite to the first face, and includes a first photoelectric conversion element and a second photoelectric conversion element sequentially arranged in a first direction, a third photoelectric conversion element and a fourth photoelectric conversion element sequentially arranged in the first direction, and a floating diffusion portion shared by the first photoelectric conversion element, the second photoelectric conversion element, the third photoelectric conversion element, and the fourth photoelectric conversion element,
wherein the first photoelectric conversion element and the third photoelectric conversion element are sequentially arranged in a second direction intersecting with the first direction, and the second photoelectric conversion element and the fourth photoelectric conversion element are sequentially arranged in the second direction,
wherein the floating diffusion portion is disposed between the first photoelectric conversion element and the fourth photoelectric conversion element and between the second photoelectric conversion element and the third photoelectric conversion element,
wherein a first element isolation region including a trench structure is disposed between the first pixel and the second pixel,
wherein, in the first pixel, a second element isolation region including a trench structure is disposed between the first photoelectric conversion element and the second photoelectric conversion element, and a third element isolation region including a trench structure is arranged between the first photoelectric conversion element and the third photoelectric conversion element,
wherein each of the first photoelectric conversion element, the second photoelectric conversion element, the third photoelectric conversion element, and the fourth photoelectric conversion element includes a first semiconductor region of a first conductive-type configured to accumulate signal charges, and
wherein, in a planar view of the first face, an impurity concentration of a second semiconductor region of a second conductive-type disposed adjacent to the trench structure in the second element isolation region is larger than an impurity concentration of a third semiconductor region of the second conductive-type disposed adjacent to the trench structure in the third element isolation region.

5. An apparatus comprising a first pixel configured to receive light via a first microlens and a second pixel configured to receive light via a second microlens,
wherein each of the first pixel and the second pixel are arranged on a semiconductor substrate having a first face and a second face opposite to the first face, and includes a first photoelectric conversion element and a second photoelectric conversion element sequentially arranged in a first direction, a third photoelectric conversion element and a fourth photoelectric conversion element sequentially arranged in the first direction, and a floating diffusion portion shared by the first photoelectric conversion element, the second photoelectric conversion element, the third photoelectric conversion element, and the fourth photoelectric conversion element,
wherein the first photoelectric conversion element and the third photoelectric conversion element are sequentially arranged in a second direction intersecting with the first direction, and the second photoelectric conversion element and the fourth photoelectric conversion element are sequentially arranged in the second direction,
wherein the floating diffusion portion is disposed between the first photoelectric conversion element and the fourth photoelectric conversion element and between the second photoelectric conversion element and the third photoelectric conversion element,
wherein a first element isolation region including a trench structure is disposed between the first pixel and the second pixel,
wherein, in the first pixel, a second element isolation region including a trench structure is disposed between the first photoelectric conversion element and the second photoelectric conversion element, and a third element isolation region including a trench structure is disposed between the first photoelectric conversion element and the third photoelectric conversion element, and
wherein, in the second element isolation region and the third element isolation region, a depth of one trench structure is different from a depth of another trench structure.

6. The apparatus according to claim 2, wherein, in a planar view of the first face, a length in the second direction of the trench structure in the second element isolation region is larger than a length in the first direction of the trench structure in the third element isolation region.

7. The apparatus according to claim 6, further comprising a third pixel,
wherein the third pixel is disposed on the semiconductor substrate, and includes a first photoelectric conversion element and a second photoelectric conversion element that are sequentially arranged in the first direction, a third photoelectric conversion element and a fourth photoelectric conversion element that are sequentially arranged in the first direction, and a floating diffusion portion shared by the first photoelectric conversion element, the second photoelectric conversion element, the third photoelectric conversion element, and the fourth photoelectric conversion element,
wherein, in the third pixel, a second element isolation region including a trench structure is disposed between the first photoelectric conversion element and the second photoelectric conversion element, and a third element isolation region including a trench structure is disposed between the first photoelectric conversion element and the third photoelectric conversion element, and
wherein, in the planar view, a length in the second direction of the trench structure in the second element isolation region in the third pixel is larger than a length in the first direction of the trench structure in the third element isolation region in the third pixel.

8. The apparatus according to claim 1, wherein, in the planar view of the first face, the trench structure in the second element isolation region and the trench structure in the third element isolation region are connected to the trench structure in the first element isolation region.

9. The apparatus according to claim 4, wherein, in the planar view, the trench structure in the second element isolation region is connected to the trench structure in the first element isolation region, and the trench structure in the third element isolation region is not connected to the trench structure in the first element isolation region.

10. The apparatus according to claim 1,
wherein each of the second element isolation region and the third element isolation region includes an insulator, and
wherein an area of the insulator in the second element isolation region is different from an area of the insulator in the third element isolation region.

11. The apparatus according to claim 8, wherein each of the second element isolation region and the third element isolation region includes a semiconductor region of a conductive type different from a conductive type of signal charges.

12. The apparatus according to claim 1, wherein each of the trench structure in the second element isolation region and the trench structure in the third element isolation region is formed to have a depth not penetrating the semiconductor substrate.

13. The apparatus according to claim 2, wherein each of the trench structure in the second element isolation region and the trench structure in the third element isolation region is formed to have a depth not penetrating the semiconductor substrate.

14. The apparatus according to claim 1, wherein a potential with respect to signal charges in the second element isolation region is larger than a potential with respect to signal charges in the third element isolation region.

15. The apparatus according to claim 2, wherein a potential with respect to signal charges in the second element isolation region is larger than a potential with respect to signal charges in the third element isolation region.

16. The apparatus according to claim 3, wherein a potential with respect to signal charges in the second element isolation region is larger than a potential with respect to signal charges in the third element isolation region.

17. The apparatus according to claim 4, wherein a potential with respect to signal charges in the second element isolation region is larger than a potential with respect to signal charges in the third element isolation region.

18. The apparatus according to claim 5, wherein a potential with respect to signal charges in the second element isolation region is larger than a potential with respect to signal charges in the third element isolation region.

19. The apparatus according to claim 1,
wherein a transfer gate is disposed between the first photoelectric conversion element and the floating diffusion portion, and
wherein the transfer gate is disposed to extend toward the second face from the first face.

20. The apparatus according to claim 1, wherein the trench structure in the first element isolation region penetrates from the first face to the second face.

21. The apparatus according to claim 2, wherein the trench structure in the first element isolation region penetrates from the first face to the second face.

22. The apparatus according to claim 3, wherein the trench structure in the first element isolation region penetrates from the first face to the second face.

23. The apparatus according to claim 4, wherein the trench structure in the first element isolation region penetrates from the first face to the second face.

24. The apparatus according to claim 5, wherein the trench structure in the first element isolation region penetrates from the first face to the second face.

25. The apparatus according to claim 1,
wherein, in the first pixel, a fourth element isolation region including a trench structure is disposed between the third photoelectric conversion element and the fourth photoelectric conversion element, and a fifth element isolation region including a trench structure is arranged between the second photoelectric conversion element and the fourth photoelectric conversion element, and
wherein, in a planar view of the first face, a length in the first direction of the trench structure in the fourth element isolation region is substantially the same as a length in the second direction of the trench structure in the fifth element isolation region.

26. The apparatus according to claim 2,
wherein, in the first pixel, a fourth element isolation region including a trench structure is disposed between the third photoelectric conversion element and the fourth photoelectric conversion element, and a fifth element isolation region including a trench structure is arranged between the second photoelectric conversion element and the fourth photoelectric conversion element, and
wherein, in a planar view of the first face, a length in the second direction of the trench structure in the fourth element isolation region is substantially the same as a length in the first direction of the trench structure in the fifth element isolation region.

27. The apparatus according to claim 3,
wherein, in the first pixel, a fourth element isolation region including a trench structure is disposed between the third photoelectric conversion element and the fourth photoelectric conversion element, and a fifth element isolation region including a trench structure is arranged between the second photoelectric conversion element and the fourth photoelectric conversion element, and
wherein, in a planar view of the first face, a length in the first direction of the fourth semiconductor region of the second conductive type disposed adjacent to the trench structure in the fourth element isolation region is substantially the same as a length in the second direction of the fifth semiconductor region of the second conductive type disposed adjacent to the trench structure in the fifth element isolation region.

28. The apparatus according to claim 4,
wherein, in the first pixel, a fourth element isolation region including a trench structure is disposed between the third photoelectric conversion element and the fourth photoelectric conversion element, and a fifth element isolation region including a trench structure is disposed between the second photoelectric conversion element and the fourth photoelectric conversion element, and
wherein, in a planar view of the first face, an impurity concentration of the fourth semiconductor region of the second conductive type disposed adjacent to the trench structure in the fourth element isolation region is substantially the same as an impurity concentration of the fifth semiconductor region of the second conductive type disposed adjacent to the trench structure in the fifth element isolation region.

29. The apparatus according to claim 5,
wherein, in the first pixel, a fourth element isolation region including a trench structure is disposed between the third photoelectric conversion element and the fourth photoelectric conversion element, and a fifth element isolation region including a trench structure is disposed between the second photoelectric conversion element and the fourth photoelectric conversion element, and
wherein, in a planar view of the first face, a depth of the trench structure in the fourth element isolation region is substantially the same as a depth of the trench structure in the fifth element isolation region.

30. An equipment comprising the apparatus according to claim 1, further comprising at least any one of:
an optical apparatus configured to guide light to the apparatus;
a control apparatus configured to control the apparatus;
a processing apparatus configured to process a signal output from the apparatus;
a display apparatus configured to display information acquired by the apparatus;
a storage apparatus configured to store information acquired by the apparatus; or
a mechanical apparatus configured to operate based on the information acquired by the apparatus.
